(19) United States
(12) Patent Application Publication
(10) Pub. No.: US 2021/0153357 A1
(43) Pub. Date: May 20, 2021

(54) CROSS-WIRING CALIBRATION AND POSITIONING METHOD FOR SOLDER PASTE PRINTING OF SINGLE OR MULTIPLE PIECES OF PCB OR FPC

(71) Applicant: USUN TECHNOLOGY CO., LTD., Foshan City (CN)

(72) Inventors: Geoffrey GUO, Foshan City (CN); Cheng Chang YANG, Foshan City (CN)

(21) Appl. No.: 17/158,311

(22) Filed: Jan. 26, 2021

Related U.S. Application Data
(63) Continuation of application No. PCT/CN2019/083412, filed on Apr. 19, 2019.

(30) Foreign Application Priority Data
Mar. 27, 2019 (CN) 201910238143.9

(51) Int. Cl. H05K 3/34; B23K 3/06; B23K 37/04; H05K 3/00

(52) U.S. Cl. CPC H05K 3/341; B23K 3/0638; B23K 2101/42; H05K 3/0008; H05K 3/3485; B23K 37/0408

(57) ABSTRACT

A cross-wiring calibration and positioning method for solder paste printing of a single or multiple pieces of PCB or FPC is provided including: lifting a PCB and FPC to disengage from a lower carrier for suction positioning, recording coordinates by photographing marker points of two points on each single piece of PCB or FPC, comparing the same with absolute coordinates or relative coordinates of marker point coordinates on a solder paste printing steel plate photographed through a solder paste printer, performing compensation calculation and feeding back a signal to an XYθ calibration platform on each profiling sucker, lifting the PCB or the FPC to attach to the solder paste printing steel plate for solder paste printing, lowering the lifted platform, and moving the load to a lower workstation, and then covering the PCB or FPC with an upper steel sheet or an upper carrier.

### CROSS-REFERENCE TO RELATED APPLICATIONS

This application is a continuation of international application No. PCT/CN2019/083412, filed Apr. 19, 2019, which claims priority from Chinese patent application No. 201910238143.9, filed Mar. 27, 2019, the contents of each of which are incorporated herein by reference in their entirety.

### FIELD OF THE INVENTION

The present disclosure relates to the field of SMC(T) cross-wiring devices, and more particularly, to a cross-wiring calibration and positioning method for solder paste printing of single or multiple pieces of PCB (printed circuit board) or FPC (flexible printed circuit) subjected to compensation calculation through visual software.

### BACKGROUND

Existing cross-wiring solder paste printers all employ a whole panel for solder paste printing. A whole panel yield of a single piece of PCB or a FPC solder paste printing workpiece does not reach 100% during production, and there will be several pieces of defective products. In the case of the solder paste printing of the whole panel, the cross-wiring solder paste printer has a stiff problem in mechanism due to a solder paste printing steel plate, and the piece of defective products cannot be bypassed by system operation. The traditional method for the defective piece is to manually apply a kraft paper tape to cover the piece in order to avoid waste of solder paste. The additional thickness from the paper would affect the overall printing quality and is prone to short-circuit. It also lead to additional human labor and thus higher cost.

### SUMMARY

In order to overcome the defects in the existing technology, the present disclosure provides a cross-wiring calibration and positioning method for solder paste printing of single or multiple pieces of PCB or FPC.

The technical solutions used in the present disclosure to solve the technical problem are as follows.

A cross-wiring calibration and positioning method for solder paste printing of single or multiple pieces of PCB or FPC includes the following steps of:
1) delivering a lower carrier to a loading region by lifting a lower turning conveying carrier-plate feeder;
2) grasping and transferring a PCB or FPC solder paste printing material to the loading region, fitting the material in a positioning pin of the lower carrier, and conveying the material to a lifted photographing workstation after positioning;
3) photographing, by a printer marker camera of a solder paste printer, a marker point of a solder paste printing steel plate, and transmitting coordinates to the lifted photographing workstation;
4) performing, by a high-precision electric cylinder in the lifted photographing workstation, first-stage lifting which is to lift the PCB or FPC solder paste printing material to be a position higher than the lower carrier by suction mode or adhesion; and photographing, by an upper marker camera in the lifted photographing workstation, a marker point of the PCB or FPC solder paste printing material;
5) according to the coordinates of the marker point of the solder paste printing steel plate photographed in the step 3), transmitting, by the lifted photographing workstation, a compensation value to an XYθ calibration platform through coordinate signal handshaking to correct the coordinates of the marker point of the PCB or FPC solder paste printing material;
6) conveying the corrected PCB or FPC solder paste printing material to the solder paste printer through a high precision low profile linear robot, performing, by the high-precision electric cylinder in the lifted photographing workstation, second-stage lifting which is to lift the PCB or FPC solder paste printing material to the solder paste printing steel plate, and attaching the material for solder paste printing;
7) after the solder paste printing is completed, lowering the lifted photographing workstation which has two stages: first, lowering the lifted photographing workstation to complete demoulding of the PCB or FPC solder paste printing material, and second, lowering the lifted photographing workstation to complete positioning of the PCB or FPC solder paste printing material fitted in the positioning pin of the lower carrier, and conveying the material to a steel sheet capping machine to complete buffer positioning;
8) fixing and grasping, by a Y-axis servo sliding table and a Z-axis servo sliding table, an upper steel sheet and covering the upper steel sheet to an upper end of the lower carrier to complete front fixing of an SMT chip.

As a preferred option, in the step 1), the lower carriers are delivered to a first AB switching-type conveying station by lifting the lower turning conveying carrier-plate feeder, the lower carriers are respectively conveyed to separate loading regions in an alternating manner, and the lower carriers are respectively conveyed to the lifted photographing workstation in an alternating manner through a second AB switching-type conveying station from the loading regions.

As a preferred option, in the step 1), the PCB or FPC solder paste printing material is sucked and transferred into the loading region through a robotic arm equipped with suction module.

As a preferred option, in the step 1), the PCB or FPC solder paste printing material is grasped and transferred into the loading region through a robotic arm equipped with a clamping claw.

As a preferred option, in the step 1), the PCB or FPC solder paste printing material is sucked and transferred into the loading region through an XYZ linear sliding table (line code) equipped with suction module.

As a preferred option, in the step 1), the PCB or FPC solder paste printing material is grasped and transferred into the loading region through an XYZ linear sliding table (line code) equipped with a clamping claw.

As a preferred option, in the step 8), a suction mode or an adhesion mode and a positioning pin positioning mode are employed as the fixing modes.

The present disclosure has the beneficial effects that: the cross-wiring solder paste printing device for the multiple pieces of fully qualified PCB (printed circuit board) or FPC (flexible printed circuit), which performs the steps of cross-wiring, transfer and delivery, material taking and discharge, independent suction type XYθ calibration platform, high-speed transfer, multi-stage lifting, and alternating plate feeding without idling, and the high-precision solder paste printing process mode can effectively improve production efficiency (fully qualified PCB or FPC), lower costs (without waste of older paste, thus environmental friendly), and shorten labor-hours for processing NG plates (the solder paste printing of fully qualified PCB or FPC), and multiple visual calibrations and signal handshaking for checking a coordinate effect are performed to maintain high-precision, high-accuracy, high-quality and high-yield cross-wiring solder paste printing, thus effectively reducing technical manpower and heavy labor (cost reduction) and achieving a more efficient production and manufacturing process technology.

### BRIEF DESCRIPTION OF THE DRAWINGS

The present disclosure is further described hereinafter with reference to the accompanying drawings and the embodiments.

FIG. 1 shows a schematic diagram of step 1 of the present disclosure;

FIG. 2 shows a schematic diagram of step 2 of the present disclosure;

FIG. 3 shows a schematic diagram of step 3 of the present disclosure;

FIG. 4 shows a schematic diagram of step 4 of the present disclosure;

FIG. 5 shows a schematic diagram of step 5 of the present disclosure;

FIG. 6 shows a schematic diagram of step 6 of the present disclosure;

FIG. 7 shows a schematic diagram of step 7 of the present disclosure;

FIG. 8 shows a schematic diagram of step 8 of the present disclosure;

FIG. 9 shows a schematic diagram of step 9 of the present disclosure; and

FIG. 10 shows a schematic diagram of the present disclosure.

### DETAILED DESCRIPTION OF THE EMBODIMENTS

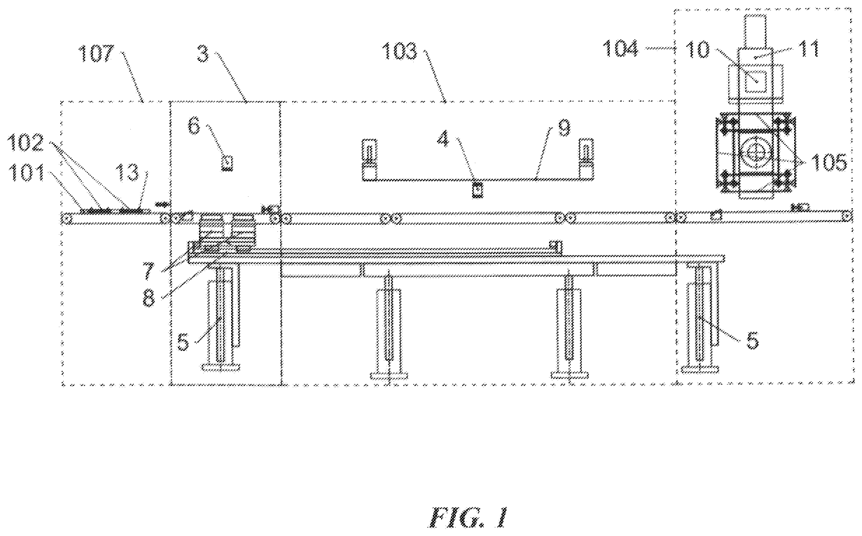

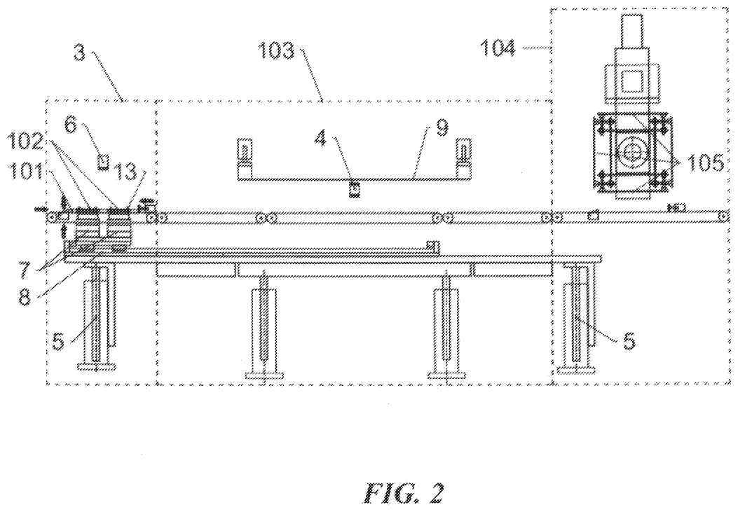

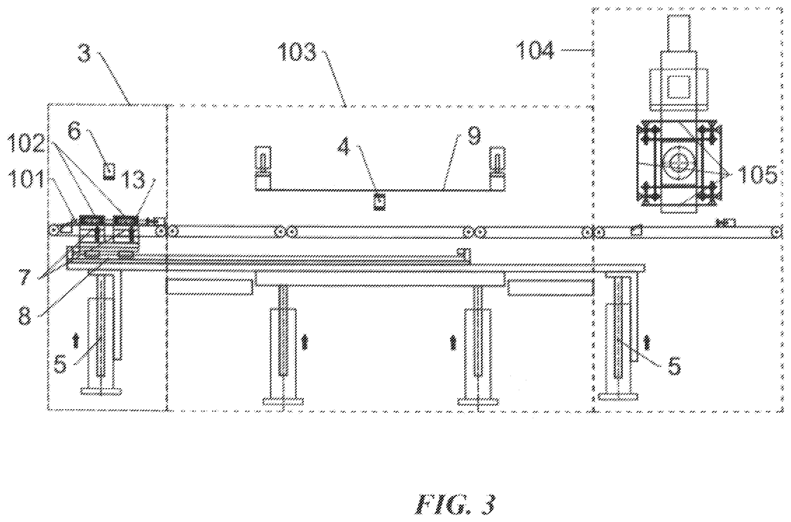

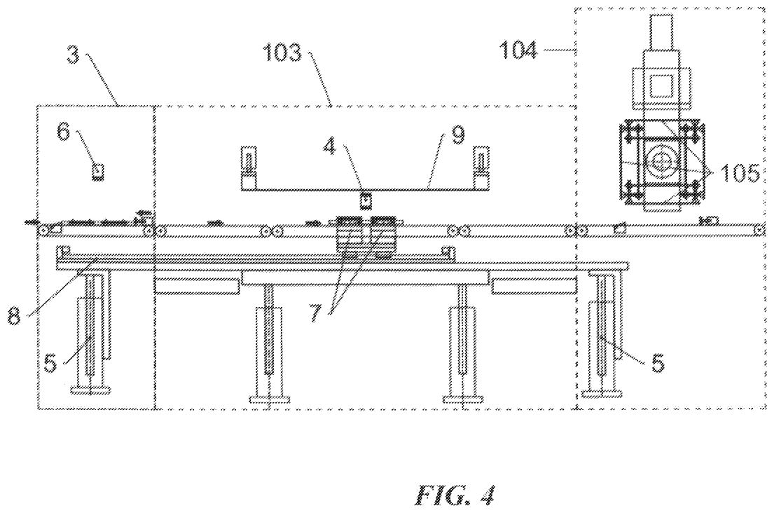

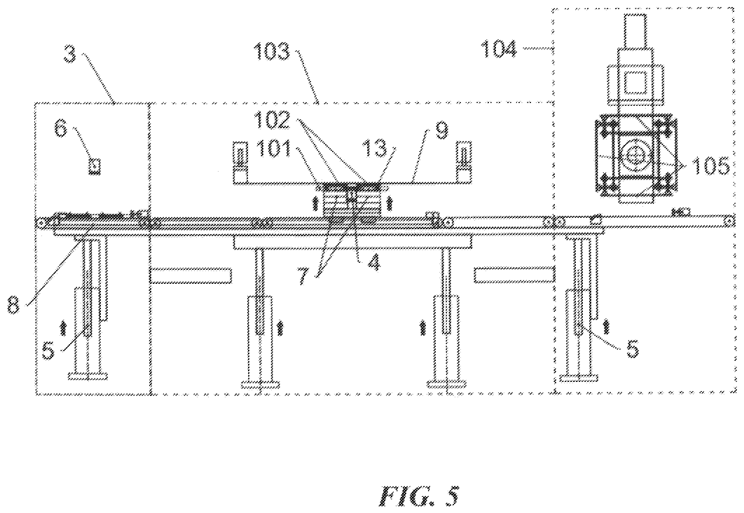

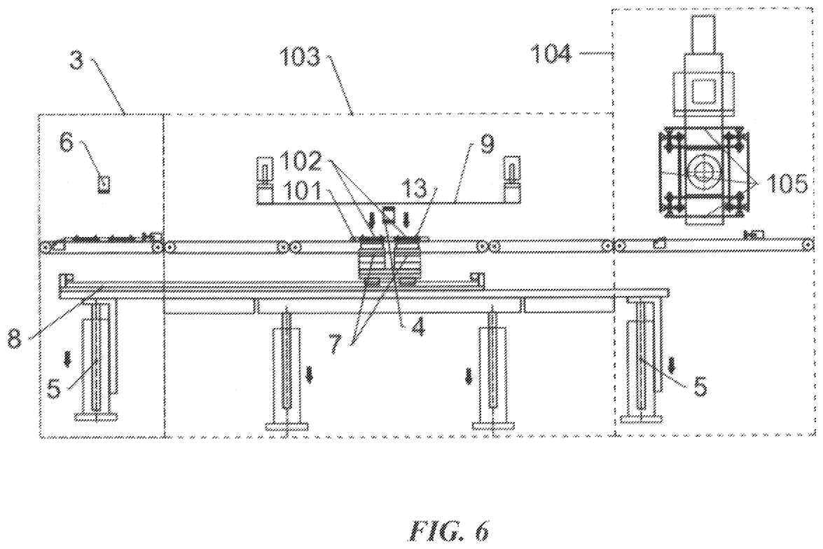

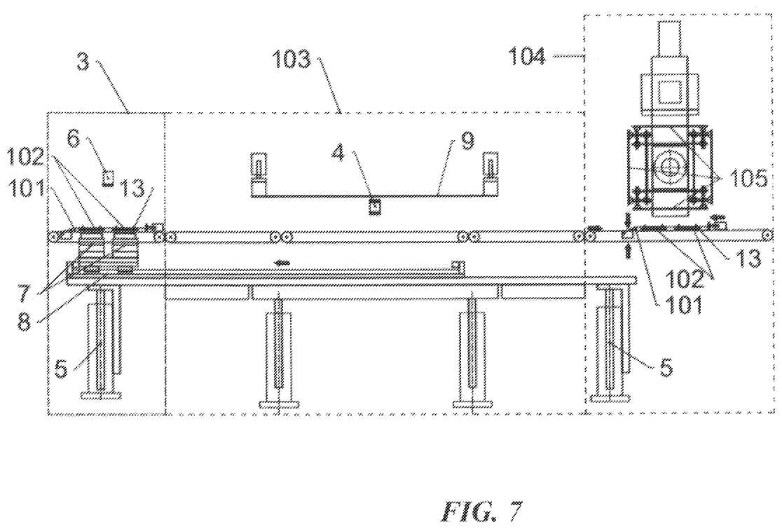

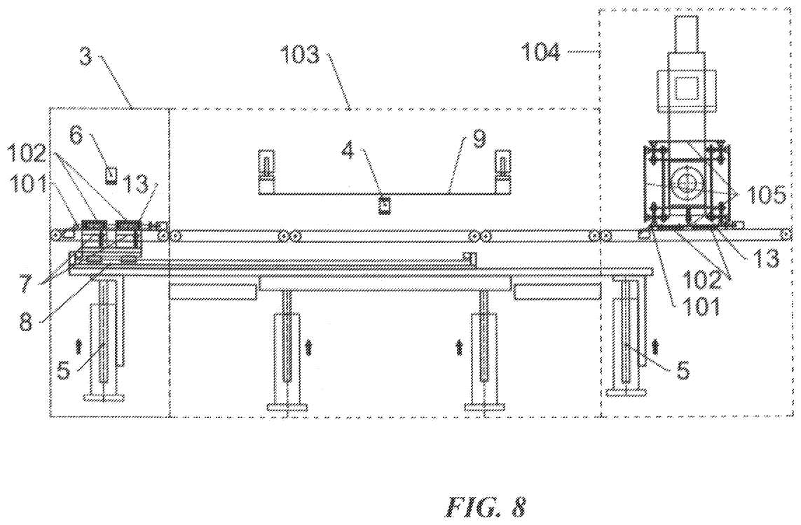

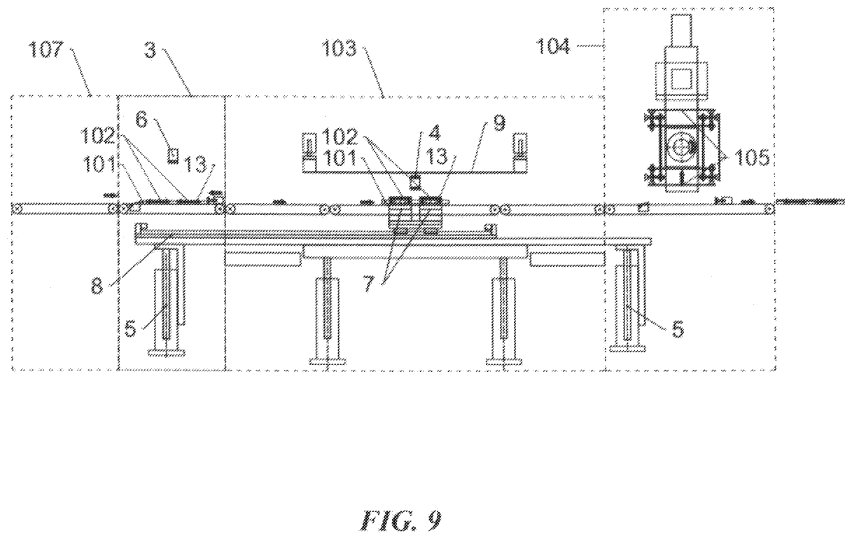

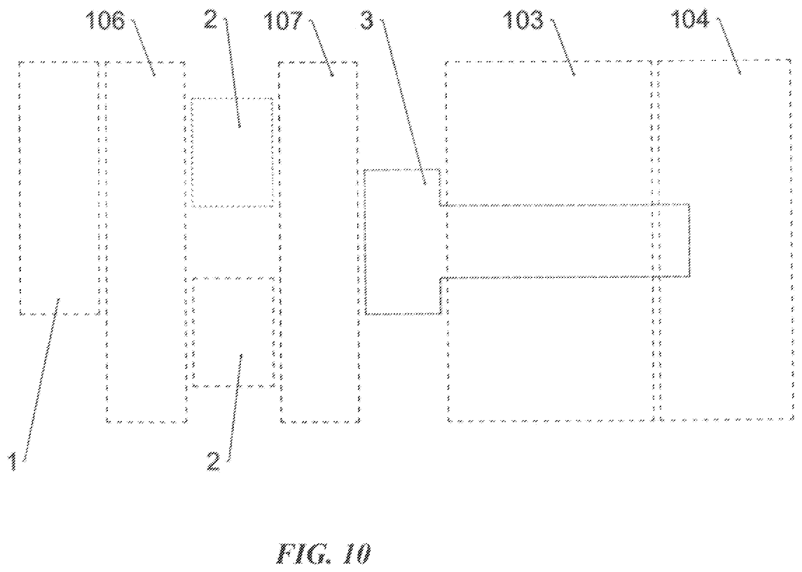

With reference to FIG. 1 to FIG. 10, the present disclosure employs single piece correction compensation positioning high-speed transfer high-precision solder paste printing, adopts a design of a calibration compensation mode that performs online single-machine or multi-device wiring production, and provides a cross-wiring calibration platform method for solder paste printing of a single or multiple pieces of PCB or FPC. The method includes the following steps of:
1) delivering a lower carrier 101 to a loading region 2 by lifting a lower turning conveying carrier-plate feeder 1;
2) grasping and transferring a PCB or FPC solder paste printing material 102 to the loading region 2, fitting the material in a positioning pin 13 of the lower carrier 101, and conveying the material to a lifted photographing workstation 3 after positioning;
3) photographing, by a printer marker camera 4 of a solder paste printer 103, a marker point of a solder paste printing steel plate, and transmitting coordinates to the lifted photographing workstation 3;
4) performing, by a high-precision electric cylinder 5 in the lifted photographing workstation 3, first-stage lifting which is to lift the PCB or FPC solder paste printing material 102 to be a position higher than the lower carrier 101 by suction mode or adhesion; and photographing, by an upper marker camera 6 in the lifted photographing workstation 3, a marker point of the PCB or FPC solder paste printing material 102;
5) according to the coordinates of the marker point of the solder paste printing steel plate photographed in the step 3), transmitting, by the lifted photographing workstation 3, a compensation value to an XYθ calibration platform 7 through coordinate signal handshaking to correct the coordinates of the marker point of the PCB or FPC solder paste printing material 102;
6) conveying the corrected PCB or FPC solder paste printing material 102 to the solder paste printer 103 through a high precision low profile linear robot 8, performing, by the high-precision electric cylinder 5 in the lifted photographing workstation 3, second-stage lifting which is to lift the PCB or FPC solder paste printing material 102 to the solder paste printing steel plate 9, and attaching the material for solder paste printing;
7) after the solder paste printing is completed, lowering the lifted photographing workstation 3 which has two stages: first, lowering the lifted photographing workstation to complete demoulding of the PCB or FPC solder paste printing material 102, and second, lowering the lifted photographing workstation to complete positioning of the PCB or FPC solder paste printing material 102 fitted in the positioning pin 13 of the lower carrier 101, and conveying the material to a steel sheet capping machine 104 to complete buffer positioning;
8) fixing and grasping, by a Y-axis servo sliding table 10 and a Z-axis servo sliding table 11, an upper steel sheet 105 and covering the upper steel sheet to an upper end of the lower carrier 101 to complete front fixing of an SMT chip.

The method can effectively improve a production efficiency and lower costs, is environmentally friendly, shortens PASS labor-hours for processing NG plates, and has the advantages of effectively maintaining high-precision cross-wiring solder paste printing and high-quality solder paste printing, and reducing manpower and repeated work.

In the above step 8), a suction mode or an adhesion mode and a positioning pin positioning mode are employed as the fixing modes.

The PCB or FPC solder paste printing material 102 may be delivered and positioned through a robotic arm equipped with suction module or a clamping claw, and an XYZ linear sliding table equipped with suction module or the clamping claw.

In order to improve a working efficiency, the lower carrier 101 is delivered to a first AB switching-type conveying station 106 by lifting a lower turning conveying carrier-plate feeder 1. The first AB switching-type conveying station 106 alternately transports the lower carrier 101 to a first loading region or a second loading area, and the first loading area or the second loading area alternately transports the PCB or FPC solder paste printing material 102 positioned with the lower carrier 101 through a second AB switching-type conveying station 107.

According to the above principle, the above embodiments may also be appropriately changed and modified in the present disclosure. Therefore, the present disclosure is not limited to the specific embodiments disclosed and described above, and some modifications and changes to the present disclosure shall also fall within the scope of protection of the claims of the present disclosure.

What is claimed is:

1. A cross-wiring calibration and positioning method for solder paste printing of a single or multiple pieces of PCB or FPC, comprising the following steps of:
1) delivering a lower carrier (101) to a loading region (2) by lifting a lower turning conveying carrier-plate feeder (1);
2) grasping and transferring a PCB or FPC solder paste printing material (102) to the loading region (2), fitting the material in a positioning pin (13) of the lower carrier (101), and conveying the material to a lifted photographing workstation (3) after positioning;
3) photographing, by a printer marker camera (4) of a solder paste printer (103), a marker point of a solder paste printing steel plate, and transmitting coordinates to the lifted photographing workstation (3);
4) performing, by a high-precision electric cylinder (5) in the lifted photographing workstation (3), first-stage lifting which is to lift the PCB or FPC solder paste printing material (102) to be a position higher than the lower carrier (101) by suction mode or adhesion; and photographing, by an upper marker camera (6) in the lifted photographing workstation (3), a marker point of the PCB or FPC solder paste printing material (102);
5) according to the coordinates of the marker point of the solder paste printing steel plate photographed in the step 3), transmitting, by the lifted photographing workstation (3), a compensation value to an XYθ calibration platform (7) through coordinate signal handshaking to correct the coordinates of the marker point of the PCB or FPC solder paste printing material (102);
6) conveying the corrected PCB or FPC solder paste printing material (102) to the solder paste printer (103) through a high precision low profile linear robot (8), performing, by the high-precision electric cylinder (5) in the lifted photographing workstation (3), second-stage lifting which is to lift the PCB or FPC solder paste printing material (102) to the solder paste printing steel plate (9), and attaching the material for solder paste printing;
7) after the solder paste printing is completed, lowering the lifted photographing workstation (3) which has two stages: first, lowering the lifted photographing workstation to complete demoulding of the PCB or FPC solder paste printing material (102), and second, lowering the lifted photographing workstation to complete positioning of the PCB or FPC solder paste printing material (102) fitted in the positioning pin (13) of the lower carrier (101), and conveying the material to a steel sheet capping machine (104) to complete buffer positioning;
8) fixing and grasping, by a Y-axis servo sliding table (10) and a Z-axis servo sliding table (11), an upper steel sheet (105) and covering the upper steel sheet to an upper end of the lower carrier (101) to complete front fixing of an SMT chip.

2. The cross-wiring calibration and positioning method for solder paste printing of a single or multiple pieces of PCB or FPC according to claim 1, wherein in the step 1), the lower carriers (101) are delivered to a first AB switching-type conveying station (106) by lifting the lower turning conveying carrier-plate feeder (1), the lower carriers (101) are respectively conveyed to separate loading regions (2) in an alternating manner, and the lower carriers (101) are respectively conveyed to the lifted photographing workstation (3) in an alternating manner through a second AB switching-type conveying station (107) from the loading regions (2).

3. The cross-wiring calibration and positioning method for solder paste printing of a single or multiple pieces of PCB or FPC according to claim 1, wherein in the step 1), the PCB or FPC solder paste printing material (102) is sucked and transferred into the loading region (2) through a robotic arm equipped with suction module.

4. The cross-wiring calibration and positioning method for solder paste printing of a single or multiple pieces of PCB or FPC according to claim 1, wherein in the step 1), the PCB or FPC solder paste printing material (102) is grasped and transferred into the loading region (2) through a robotic arm equipped with a clamping claw.

5. The cross-wiring calibration and positioning method for solder paste printing of a single or multiple pieces of PCB or FPC according to claim 1, wherein in the step 1), the PCB or FPC solder paste printing material (102) is sucked and transferred into the loading region (2) through an XYZ linear sliding table (line code) equipped with suction module.

6. The cross-wiring calibration and positioning method for solder paste printing of a single or multiple pieces of PCB or FPC according to claim 1, wherein in the step 1), the PCB or FPC solder paste printing material (102) is grasped and transferred into the loading region (2) through an XYZ linear sliding table (line code) equipped with a clamping claw.

7. The cross-wiring calibration and positioning method for solder paste printing of a single or multiple pieces of PCB or FPC according to claim 1, wherein in the step 8), a suction mode or an adhesion mode and a positioning pin positioning mode are employed as the fixing modes.
